(19) United States
(12) Patent Application Publication
(10) Pub. No.: US 2026/0121001 A1
(43) Pub. Date: Apr. 30, 2026

(54) SUBSTRATE PROCESSING APPARATUS

(71) Applicant: Samsung Electronics Co., Ltd., Suwon-si (KR)

(72) Inventors: Nayoung Ji, Suwon-si (KR); DAIHONG KIM, Suwon-si (KR); IK SOO KIM, Suwon-si (KR); KYUNG-TAE JANG, Suwon-si (KR)

(21) Appl. No.: 19/249,005

(22) Filed: Jun. 25, 2025

(30) Foreign Application Priority Data
Oct. 30, 2024 (KR) 10-2024-0150935

(51) Int. Cl. H01J 37/32

(52) U.S. Cl. CPC H01J 37/32449; H01J 37/32568; H01J 2237/334

(57) ABSTRACT

Provided is a substrate processing apparatus including: a chamber providing a process space; a support member disposed in the chamber and configured to support a substrate; and a shower head disposed in the chamber and configured to spray a gas, wherein the shower head includes a central region and an edge spray region disposed around an outer perimeter of the central region, a control gas spray hole is disposed in the central region, and a process gas spray hole is disposed in the edge spray region.

This application claims priority under 35 U.S.C. §119 to and the benefit of Korean Patent Application No. 10-2024-0150935 filed in the Korean Intellectual Property Office on October 30, 2024, the entire contents of which are incorporated herein by reference.

### BACKGROUND OF THE INVENTION

### (a) Field of the Invention

The present disclosure relates to a substrate processing apparatus.

### (b) Description of the Related Art

In order to manufacture a semiconductor device, various processes such as photolithography, etching, ashing, ion implantation, thin film deposition, cleaning, and the like may be performed on a substrate to thus form a desired pattern on the substrate.

Some of these semiconductor manufacturing processes may be performed using plasma. In general, to form plasma, an electromagnetic field may be formed in an internal space of a chamber, and the electromagnetic field may excite a process gas provided in the chamber into a plasma state.

### SUMMARY OF THE INVENTION

Aspects of the present disclosure provide a substrate processing apparatus for processing a substrate by effectively supplying a gas for processing the substrate to a space where the substrate is disposed.

However, issues to be addressed by embodiments of the present disclosure are not limited to the above-mentioned issues and may be variously expanded from the present disclosure including the following embodiments.

According to an embodiment, provided is a substrate processing apparatus including: a chamber providing a process space; a support member disposed in the chamber and configured to support a substrate; and a shower head disposed in the chamber and configured to spray a gas, wherein the shower head includes a central region and an edge spray region disposed around an outer perimeter of the central region, a control gas spray hole is disposed in the central region, and a process gas spray hole is disposed in the edge spray region.

According to another embodiment, provided is a substrate processing apparatus including: a chamber providing a process space; a support member disposed in the chamber and configured to support a substrate; a shower head disposed in the chamber and configured to spray a gas; a process gas supply member connected to the shower head and configured to supply a process gas; a control gas supply member connected to the shower head and configured to supply a control gas; and an edge plasma excitation member configured to apply energy for exciting plasma to the process space, wherein the shower head includes a central region and an edge spray region disposed around an outer perimeter of the central region, a control gas spray hole configured to spray the control gas is disposed in the central region, and a process gas spray hole configured to spray the process gas is disposed in the edge spray region.

According to still another embodiment, provided is a substrate processing apparatus including: a chamber providing a process space; a support member disposed in the chamber and configured to support a substrate; a shower head disposed in the chamber and configured to spray a gas; a process gas supply member connected to the shower head and configured to supply a process gas; a control gas supply member connected to the shower head and configured to supply a control gas; a plasma adjustment plate disposed between the shower head and the support member; and an edge plasma excitation member configured to apply energy for exciting plasma to the process space, wherein the shower head includes a central region and an edge spray region disposed around an outer perimeter of the central region, a control gas spray hole configured to spray the control gas is disposed in the central region, and a process gas spray hole configured to spray the process gas is disposed in the edge spray region.

According to the embodiments, aspects of the present disclosure may provide the substrate processing apparatus for processing the substrate by effectively supplying the gas for processing the substrate to the space where the substrate is disposed.

### BRIEF DESCRIPTION OF THE DRAWINGS

FIG. 1 is a cross-sectional view showing a substrate processing apparatus according to an embodiment.

FIG. 2 is a bottom view of a shower head shown in FIG. 1.

FIG. 3 is a sectional view of a central region of the shower head.

FIG. 4 is a cross-sectional view showing a support member, the shower head, and a plasma adjustment plate shown in FIG. 1.

FIG. 5 is a cross-sectional view showing a flow of a gas supplied through the shower head during a processing of a substrate.

FIG. 6 is a cross-sectional view showing a bevel edge of the substrate before the processing on the substrate is performed.

FIG. 7 is a cross-sectional view showing the bevel edge of the substrate after the processing on the substrate is performed.

FIG. 8 is a cross-sectional view of a substrate processing apparatus according to another embodiment.

FIG. 9 is a bottom view of a shower head shown in FIG. 8.

FIG. 10 is a bottom view of a plasma adjustment plate shown in FIG. 8.

FIG. 11 is a cross-sectional view of a substrate processing apparatus according to still another embodiment.

FIG. 12 is a bottom view of a shower head shown in FIG. 11.

FIG. 13 is a cross-sectional view of a substrate processing apparatus according to yet another embodiment.

FIG. 14 is a cross-sectional view of a substrate processing apparatus according to a further embodiment.

### DETAILED DESCRIPTION OF THE EMBODIMENTS

Hereinafter, various embodiments of the present disclosure are described in detail with reference to the accompanying drawings so that those skilled in the art to which the present disclosure pertains may easily practice the present disclosure. The present disclosure may be implemented in various different forms and is not limited to the embodiments described herein.

Portions not closely related to main features of the embodiments may be omitted in order for brevity of description of the present disclosure, and the same or similar components are denoted by the same reference numerals throughout the specification, and repeated descriptions thereof may also be omitted for brevity of description.

In addition, the size and thickness of each component shown in the accompanying drawings are arbitrarily shown for convenience of description, and therefore, the present disclosure is not necessarily limited to sizes shown in the drawings unless the context indicates otherwise. The thicknesses are exaggerated in the drawings in order to clearly represent several layers and regions. In addition, the thicknesses of some layers and regions are exaggerated in the drawings for convenience of description.

In addition, when an element such as a layer, a film, a region, or a plate is referred to as being "on" or "above" another element, the element may be "directly on" another element or may have a third element interposed therebetween. On the other hand, when an element is referred to as being "directly on" another element, there is no third element interposed therebetween. In addition, when an element is referred to as being "on" or "above" a reference element, the element may be disposed on or below the reference element, and may not necessarily be "on" or "above" the reference element in an opposite direction of gravity. For example, spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

In addition, when any one part "includes" any one component, it may indicate the inclusion of other components rather than the exclusion of other components unless explicitly described to the contrary.

In addition, throughout the specification, an expression "plan view" may indicate a case where a target is viewed from the top, and an expression "on the cross section" or “cross-sectional view” may indicate a case where a cross section of the target taken in a vertical direction is viewed from its side.

Throughout the specification, when a component is described as "including" a particular element or group of elements, it is to be understood that the component is formed of only the element or the group of elements, or the element or group of elements may be combined with additional elements to form the component, unless the context clearly and/or explicitly describes the contrary.

As used herein, components described as being “electrically connected” are configured such that an electrical signal can be transferred from one component to the other (although such electrical signal may be attenuated in strength as it is transferred and may be selectively transferred).

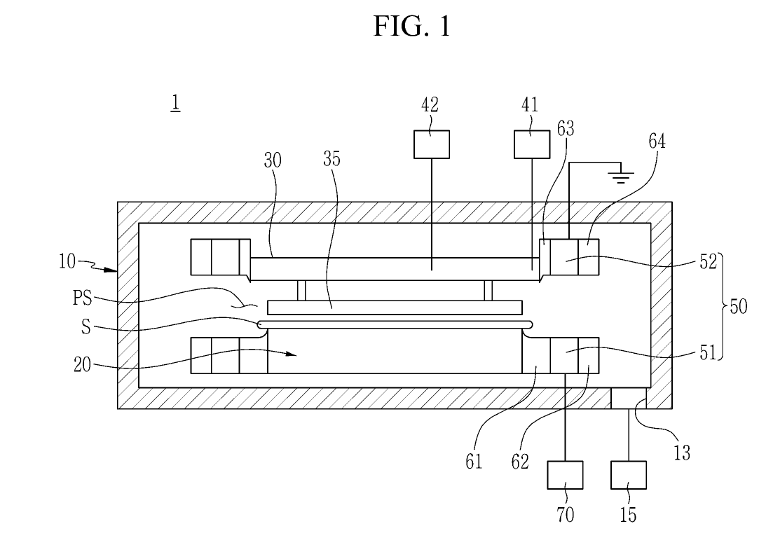

FIG. 1 is a cross-sectional view showing a substrate processing apparatus 1 according to an embodiment.

Referring to FIG. 1, the substrate processing apparatus 1 according to an embodiment may include a chamber 10, a support member 20, a shower head 30, a plasma adjustment plate 35, an edge plasma excitation member 50, and an excitation supply unit 70.

The substrate processing apparatus 1 may process a substrate S. The substrate processing apparatus 1 may process the substrate S by using plasma. The substrate processing apparatus 1 may perform a deposition process on a bevel edge region of the substrate S by using the excited plasma. For example, the substrate processing apparatus 1 may perform the deposition process on an upper surface of the edge region of the substrate S by using the excited plasma. In addition, the substrate processing apparatus 1 may perform the deposition process on a side surface of the edge region of the substrate S by using the excited plasma. In addition, the substrate processing apparatus 1 may perform the deposition process on a lower surface of the edge region of the substrate S by using the excited plasma. The substrate S may be a wafer or the like for manufacturing a semiconductor device.

The chamber 10 may provide therein a process space PS used for performing a process on the substrate. The chamber 10 may have the process space PS therein and may have a closed shape. For example, the process space PS of the chamber 10 may airtightly isolated from the outside of the chamber 10. The chamber 10 may be made of a metal. For example, chamber 10 may be made of aluminum or another metal. The chamber 10 may be grounded.

An exhaust hole 13 may be disposed/formed in one side of the chamber 10. The exhaust hole 13 may be disposed/positioned in a bottom region of the chamber 10. As an example, the exhaust hole 13 may be disposed/formed in a bottom wall of the chamber 10. A reaction by-product, a gas, or the like occurring/formed during the process and remaining in the internal space of the chamber 10 may be discharged to the outside through the exhaust hole 13. The interior of the chamber 10 may be depressurized to a predetermined pressure by an exhaust process. An exhaust member/unit 15 may be connected to the exhaust hole 13. The exhaust member 15 may apply negative pressure to the interior of the chamber 10 for an exhaust purpose. For example, the exhaust member 15 may apply the negative pressure to the interior of the chamber 10 by exhausting gas from the process space PS. In addition, the exhaust member 15 may adjust a flow rate of the gas discharged through the exhaust hole 13. The exhaust member 15 may include at least one pump. As an example, the exhaust member 15 may include a turbo molecular pump. In addition, the exhaust member 15 may include a valve or the like to adjust the flow rate of the gas discharged through the exhaust hole 13 based on a degree of opening and closing of the valve.

The support member 20 may be disposed in the chamber 10. The support member 20 may be disposed in a lower portion of the process space PS. The support member 20 may support the substrate S. The support member 20 may fix the substrate S by using an electrostatic force. The support member 20 may include a plurality of components. The support member 20 may include an electrostatic chuck. For example, the support member 20 (or each of support members in below described embodiments) may be a substrate support or a support configured such that a substrate is disposed on the support.

The electrostatic chuck may be disposed on the top of the support member 20. Accordingly, the substrate S may be disposed on an upper surface of the electrostatic chuck. The upper surface of the electrostatic chuck may be made of a dielectric material. The electrostatic chuck may fix the substrate S thereto by the electrostatic force.

A coolant path may be formed in the support member 20. The coolant path may include a path for a coolant to flow in the support member 20. As an example, the coolant path may have a spiral shape. In certain embodiments, the coolant path may include paths each formed in a shape of a ring having a different radius and the same center. Here, the coolant path may include the paths each formed in the ring shape and connected to each other. The coolant may be circulated through the coolant path to cool the support member 20. The support member 20 may be cooled to cool the substrate S disposed on the support member 20.

An area of an upper surface of the support member 20 may be smaller than an area of the substrate S. Accordingly, when the substrate S is disposed on the upper surface of the support member 20, the bevel edge region of the substrate S may protrude outward into a space where the bevel edge region faces the upper surface of the support member 20 in a vertical direction. For example, the bevel edge region of the substrate S may protrude from the upper surface of the support member in a horizontal direction.

Through the shower head 30, a gas used for processing the substrate S may be sprayed into the process space PS.

A lower surface of the shower head 30 may face the interior (e.g., a central portion) of the chamber 10. The shower head 30 may be disposed in the chamber 10. As an example, the shower head 30 may be manufactured separately from the chamber 10 and connected to the chamber 10. For example, the shower head 30 may be removal from the chamber 10, and may be installable to the chamber 10 again.

The shower head 30 may be disposed in an upper portion of the process space PS. The shower head 30 may have at least a partial region facing the support member 20 in the vertical direction. For example, the shower head 30 may be partially overlap the support member 20 in the vertical direction. The lower surface of the shower head 30 may have at least a partial region facing the upper surface of the support member 20 in the vertical direction. A lower portion of the shower head 30 may be made of an insulating material. As an example, a region of the shower head 30 that faces the upper surface of the support member 20 in the vertical direction may be made of the insulating material. In certain embodiments, an entire region of the lower surface of the shower head 30 may be made of the insulating material. An area of the lower surface of the shower head 30 may correspond to or the same as the area of the substrate S disposed on the support member 20. The area of the lower surface of the shower head 30 may be greater than the area of the upper surface of the support member 20.

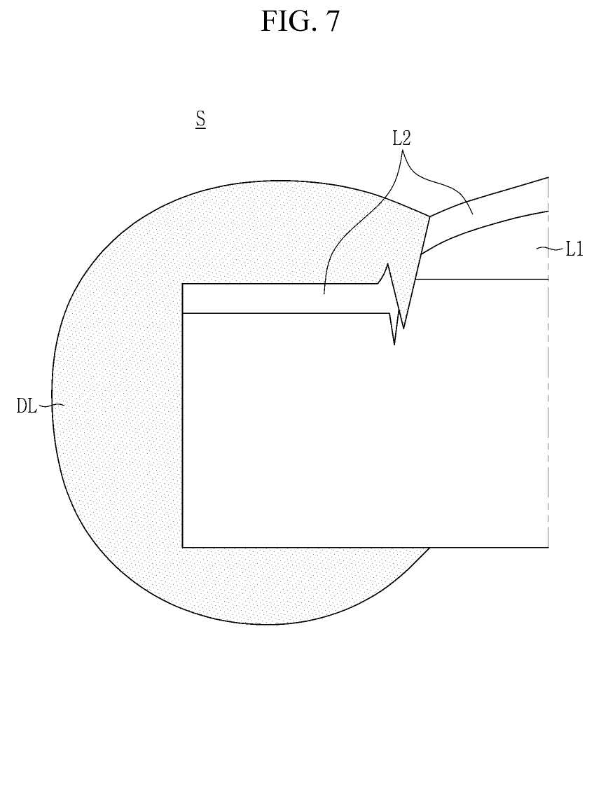

A process gas supply member 41 and a control gas supply member 42 may be connected to the shower head 30. The process gas supply member 41 may supply the process gas to the shower head 30. After the process gas is excited to the plasma state, at least some elements included in the process gas may be deposited on the substrate S to thus form a deposition layer DL (see FIG. 7). At least some elements included in the process gas may be deposited in the bevel edge region of the substrate S to thus form the deposition layer DL in the bevel edge region of the substrate S. The process gas may be a compound including a carbon atom. Accordingly, the process gas may supply a carbon ion when excited to the plasma state. As an example, the process gas may be acetylene (C₂H₂). The control gas supply member 42 may supply a deposition control gas to the shower head 30. The deposition control gas may adjust a degree to which the deposition layer DL is deposited on the substrate S. For example, the deposition control gas may adjust positions of the process gas and/or dilute portions of the process gas, e.g., by mixing with the process gas and/or by controlling amount/pressure of the deposition control gas such that positions/thicknesses of the deposition layer DL is controlled by the deposition control gas. The deposition control gas may prevent the deposition layer DL from being formed in a region other than the bevel edge region of the substrate S. The deposition control gas may be an inert gas. For example, the deposition control gas may be a gas selected from the group consisting of nitrogen, argon, neon, helium, and a combination thereof.

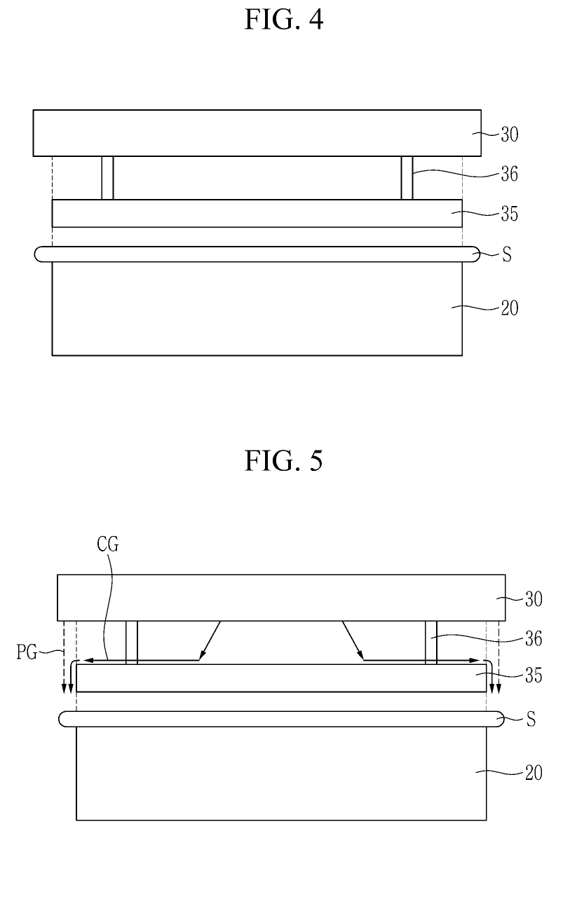

The plasma adjustment plate 35 may be disposed between the shower head 30 and the support member 20. An upper surface of the plasma adjustment plate 35 may be spaced apart from the lower surface of the shower head 30 in an up-and-down direction or the vertical direction. The plasma adjustment plate 35 may be connected to the shower head 30. As an example, the plasma adjustment plate 35 may be connected to the shower head 30 by a connection rod 36 (see FIG. 4). The plasma adjustment plate 35 may be movable in the up-and-down direction. As an example, an upper portion of the connection rod 36 may be insertable into the shower head 30. For example, a length of the connection rod 36 inserted into the shower head 30 may be changeable. As the length of the connection rod 36 inserted into the shower head 30 is changed, a separation distance between the plasma adjustment plate 35 and the shower head 30 may be adjusted, thus moving the plasma adjustment plate 35 in the up-and-down direction. The separation distance between a lower surface of the plasma adjustment plate 35 and the upper surface of the support member 20 in the up-and-down direction may be adjusted by the movement of the plasma adjustment plate 35 in the up-and-down direction.

The lower surface of the plasma adjustment plate 35 may be made of the insulating material. In certain embodiments, an entire outer surface of the plasma adjustment plate 35 may be made of the insulating material. The lower surface of the plasma adjustment plate 35 may face the upper surface of the support member 20 in the vertical direction. An area of the plasma adjustment plate 35 may be smaller than the area of the lower surface of the shower head 30. The area of the plasma adjustment plate 35 may be smaller than the area of the substrate S. The area of the plasma adjustment plate 35 may correspond to or the same as the area of the upper surface of the support member 20.

The edge plasma excitation member 50 may apply energy for exciting plasma to the process space PS. The edge plasma excitation member 50 may apply the energy for exciting plasma to a region of the support member 20 that is adjacent to its edge region. For example, the edge plasma excitation member 50 may apply the energy for exciting plasma to the bevel edge region of the substrate S disposed on the support member 20. For example, the edge plasma excitation member 50 (or each of the edge plasma excitation members in other embodiments described below) may be a plasma generator/exciter or electrodes configured to generate a plasma by applying an electric/magnetic field to a gas.

The edge plasma excitation member 50 may include a lower edge electrode 51 and an upper edge electrode 52.

The lower edge electrode 51 may be disposed in the lower portion of the process space PS. The lower edge electrode 51 may be disposed around an outer perimeter of the support member 20. The lower edge electrode 51 may have a ring structure. The lower edge electrode 51 may be made of a conductive material. A lower dielectric ring 61 may be disposed between the lower edge electrode 51 and the support member 20. A lower outer dielectric ring 62 may be disposed around an outer perimeter of the lower edge electrode 51.

The upper edge electrode 52 may be disposed in the upper portion of the process space PS. The upper edge electrode 52 may be spaced apart from the lower edge electrode 51 in the up-and-down direction or the vertical direction. The upper edge electrode 52 may have at least a partial region facing the lower edge electrode 51 in the vertical direction. For example, the upper edge electrode 52 may face and vertically overlay the lower edge electrode 51 in the vertical direction.

The upper edge electrode 52 may be disposed around an outer perimeter of the shower head 30. The upper edge electrode 52 may have the ring structure. The upper edge electrode 52 may be made of the conductive material. An upper dielectric ring 63 may be disposed between the upper edge electrode 52 and the shower head 30. An upper outer dielectric ring 64 may be disposed around an outer perimeter of the lower edge electrode 52.

The excitation supply unit 70 may provide power for exciting plasma. The excitation supply unit 70 may include a high frequency power source that generates high frequency power. The excitation supply unit 70 may include a radio frequency (RF) power source. For example, the excitation supply unit 70 may be a power supply or a power source configured to supply electric power to the excitation member 50.

The excitation supply unit 70 may be electrically connected to the edge plasma excitation member 50. The excitation supply unit 70 may be electrically connected to at least one of the lower edge electrode 51 and the upper edge electrode 52. The excitation supply unit 70 may be electrically connected to the lower edge electrode 51. In certain embodiments, the excitation supply unit 70 may be electrically connected to the upper edge electrode 52. In certain other embodiments, two excitation supply units 70 may be provided, and the excitation supply units 70 may respectively be electrically connected to the upper edge electrode 52 and the lower edge electrode 51. FIG. 1 shows a case where the excitation supply unit 70 is electrically connected to the lower edge electrode 51 and the upper edge electrode 52 is grounded.

The process gas introduced into the chamber 10 may be excited into plasma by the electromagnetic field formed in the chamber 10. For example, the process gas may be excited into plasma by a capacitively coupled plasma (CCP) source. The capacitively coupled plasma source may include the upper edge electrode 52 and the lower edge electrode 51. The upper edge electrode 52 and the lower edge electrode 51 may face each other in the chamber 10 in the up-and-down direction. High frequency power may be applied to at least one of the upper edge electrode 52 and the lower edge electrode 51, thus forming the electromagnetic field in a space between the upper edge electrode 52 and the lower edge electrode 51, and exciting the process gas supplied to this space into the plasma state. The high frequency power source may be electrically connected to only one of the upper edge electrode 52 and the lower edge electrode 51. As an example, the upper edge electrode 52 may be grounded, and the high frequency power source may be electrically connected only to the lower edge electrode 51. In certain embodiments, the lower edge electrode 51 may be grounded, and the high frequency power source may be electrically connected to only the upper edge electrode 52. In certain other embodiments, the high frequency power source may be electrically connected to both the upper edge electrode 52 and the lower edge electrode 51. FIG. 1 shows a case where the high frequency power source is electrically connected to the lower edge electrode 51.

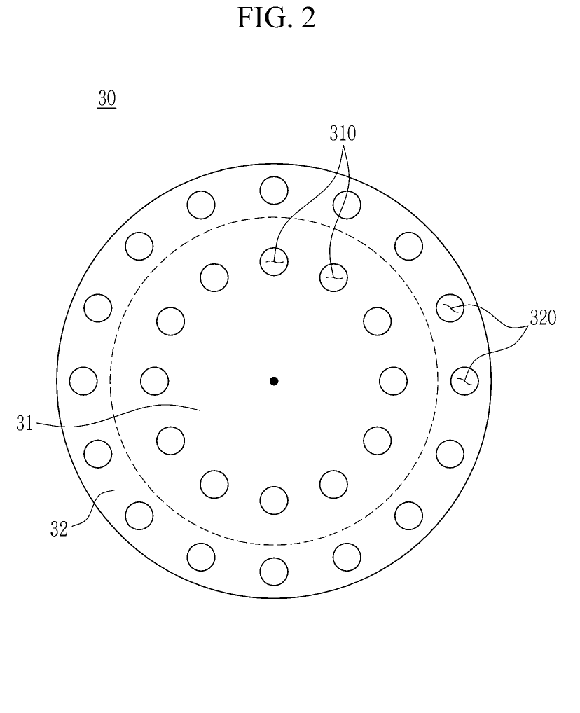

FIG. 2 is a bottom view of the shower head 30 shown in FIG. 1.

Referring to FIG. 2, a lower surface of the shower head 30 may include a central region 31 and an edge spray region 32.

The central region 31 may have a predetermined area. The area of the central region 31 may be the same as or smaller than the area of the plasma adjustment plate 35. The central region 31 may be disposed within a region of the shower head 30 that faces the plasma adjustment plate 35 in the vertical direction. For example, the central region 31 of the shower head 30 may be a region vertically overlapping the plasma adjustment plate 35.

The edge spray region 32 may be disposed around an outer perimeter of the central region 31. For example, the edge spray region 32 of the shower head 30 may be a region which does not vertically overlapping the plasma adjustment plate 35. The edge spray region 32 may be formed in the ring shape. FIG. 2 shows a case where the central region 31 has a circular shape. However, the shape of the central region 31 is not limited to this shape, and may have a polygonal shape, another shape, or the like.

Gas spray holes 310 and 320 may be disposed/formed in the lower surface of the shower head 30. Through the gas spray holes 310 and 320, the gas may be sprayed into a space below the shower head 30. The gas spray holes 310 and 320 may include a control gas spray hole 310 and a process gas spray hole 320.

The process gas spray hole 320 may be disposed in the edge spray region 32 of the shower head 30. A plurality of process gas spray holes 320 may be provided in the edge spray region 32. The process gas spray holes 320 may be connected to the process gas supply member 41. Accordingly, the process gas supplied by the process gas supply member 41 may be sprayed into the space below the shower head 30 through the process gas spray holes 320.

The control gas spray hole 310 may be disposed in the central region 31 of the shower head 30. A plurality of control gas spray holes 310 may be provided in the central region 31. The control gas spray holes 310 may be connected to the control gas supply member 42. Accordingly, the control gas supplied by the control gas supply member 42 may be sprayed into the space below the shower head 30 through the control gas spray holes 310.

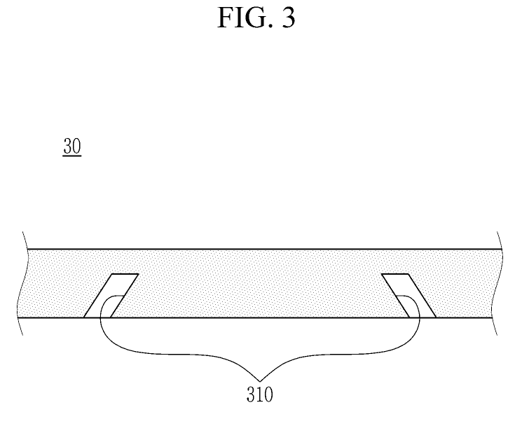

FIG. 3 is a sectional view of the central region of the shower head 30.

Referring to FIG. 3, the control gas spray hole 310 may have its length direction inclined relative to the vertical direction. As an example, the control gas spray hole 310 may have its bottom closer to the edge spray region 32 of the shower head 30 than its top. For example, the control gas spray hole 310 may be oriented from the central region of the shower head 30 toward the edge spray region 32 of the shower head 30 by extending from its top to bottom in its length direction.

FIG. 4 is a cross-sectional view showing the support member 20, the shower head 30, and the plasma adjustment plate 35 shown in FIG. 1.

Referring to FIG. 4, when the substrate S is disposed on the support member 20, a lower surface of the plasma adjustment plate 35 may face an upper surface of the substrate S. In addition, the plasma adjustment plate 35 may be moved in the up-and-down direction, thus adjusting the separation distance between the lower surface of the plasma adjustment plate 35 and the substrate S disposed on the support member 20 in the up-and-down direction. The plasma adjustment plate 35 may prevent plasma from being excited in its region facing the substrate S, e.g., between and vertically overlapping the plasma adjustment plate 35 and the substrate S. For example, in order for plasma to be excited and maintained in a space, a size of the corresponding space may be needed to satisfy a condition related to a Debye length. Accordingly, a space formed between the plasma adjustment plate 35 and the substrate S may be prevented from satisfying the condition related to the Debye length, thereby preventing plasma from being excited in a space on the substrate S that faces the plasma adjustment plate 35.

The area of the upper surface of the support member 20 may be smaller than the area of the substrate S, and the bevel edge region of the substrate S may thus protrude outward from the space where the substrate S faces the upper surface of the support member 20 in the vertical direction. For example, when the substrate S is disposed on the support member 20, the bevel edge region of the substrate S may not vertically overlap the upper surface of the support member 20 and/or may not vertically overlap the support member 20. For example, the bevel edge region of the substrate S may horizontally protrude from an edge of the upper surface of the support member 20 and/or from an edge and/or a side surface of the support member 20 as shown in FIG. 4. For example, a diameter of the substrate S may be greater than a diameter of the upper surface of the support member 20, e.g., in a plan view.

The area of the plasma adjustment plate 35 may be smaller than the area of the substrate S, and the bevel edge region of the substrate S may thus protrude outward from the space where the substrate S faces the lower surface of the plasma adjustment plate 35 in the vertical direction. For example, a diameter of the plasma adjustment plate 35 may be less/smaller than a diameter of the substrate S disposed on the support member 20, e.g., in a plan view, and the bevel edge region of the substrate S may not vertically overlap the plasma adjustment plate 35 when the substrate is disposed on the support member 20, e.g., during a processing of the substrate S.

The area of the plasma adjustment plate 35 may be smaller than the lower surface of the shower head 30, and at least a partial region of the shower head 30 may thus protrude outward from a space where the shower head 30 faces the plasma adjustment plate 35 in the vertical direction. For example, the diameter of the plasma adjustment plate 35 may be less/smaller than a diameter of the shower head 30, and an edge portion of the shower head 30 may not vertically overlap the plasma adjustment plate 35, e.g., such that the edge portion of the shower head 30 horizontally protrude from an edge of the plasma adjustment plate 35.

The area of the central region 31 of the shower head 30 may be the same or smaller than the area of the plasma adjustment plate 35, and the central region 31 may thus be disposed within the region of the shower head 30 that faces the plasma adjustment plate 35 in the vertical direction. In addition, at least a portion of the edge spray region 32 may be disposed in the shower head 30 outside a region that faces and/or overlaps the plasma adjustment plate 35 in the vertical direction. As an example, the process gas spray hole 320 may have at least a portion disposed outside the region of the shower head 30 that faces/overlaps the plasma adjustment plate 35 in the vertical direction. In some embodiments, the process gas spray hole 320 may have its entire region disposed outside the region of the shower head 30 that faces the plasma adjustment plate 35 in the vertical direction. For example, some process gas spray holes 320 formed in the shower head 30 and/or formed on the lower surface of the shower head 30 may not vertically overlap the plasma adjustment plate 35.

FIG. 5 is a cross-sectional view showing a flow of a gas supplied through the shower head 30 during a processing of a substrate S.

Referring to FIG. 5, when the processing of the substrate is performed, the process gas supply member 41 may supply the process gas to the shower head 30, and the control gas supply member 42 may supply the control gas to the shower head 30. The control gas spray hole 310 may be disposed in the region of the shower head 30 that faces and/or overlap the plasma adjustment plate 35 in the vertical direction. Accordingly, a control gas CG may be sprayed onto the upper surface of the plasma adjustment plate 35 and then flow from a central region of the plasma adjustment plate 35 toward an edge region of the plasma adjustment plate 35. In addition, the control gas spray hole 310 may be inclined, and the control gas CG sprayed from the control gas spray hole 310 may thus more effectively flow from the central region of the plasma adjustment plate 35 toward the edge region of the plasma adjustment plate 35. For example, the control gas spray hole 310 may be inclined outwardly in a direction moving downward. For example, a lower part of the control gas spray hole 310 may be farther than an upper part of the control gas spray hole 310 from a center of the shower head in a plan view. The control gas CG may thus form a curtain while flowing along a side surface of the plasma adjustment plate 35.

A process gas PG may be directly sprayed onto the bevel edge region of the substrate S when the process gas spray hole 320 is disposed outside the region of the shower head 30 that faces and/or overlaps the plasma adjustment plate 35 in the vertical direction. In addition, the curtain of the control gas CG may be disposed between the process gas PG and the central region of the substrate S and flow along the side surface of the plasma adjustment plate 35.

In addition, the process gas PG may be sprayed onto the control gas CG when the process gas PG sprayed from the process gas spray hole 320 flows downwards, e.g., toward the plasma adjustment plate 35. Accordingly, when the control gas CG and the process gas PG flow along the side surface of the plasma adjustment plate 35, the curtain of the control gas CG may be disposed toward the central region of the substrate S, and the process gas PG may be disposed toward the bevel edge region of the substrate S. For example, the curtain of the control gas CG may touch an inner portion of an upper surface of the substrate S, e.g., a portion inner than the bevel edge region, and the process gas PG may touch an outer portion of the of the upper surface of the substrate S and a side surface of the substrate S including the bevel edge region of the substrate S.

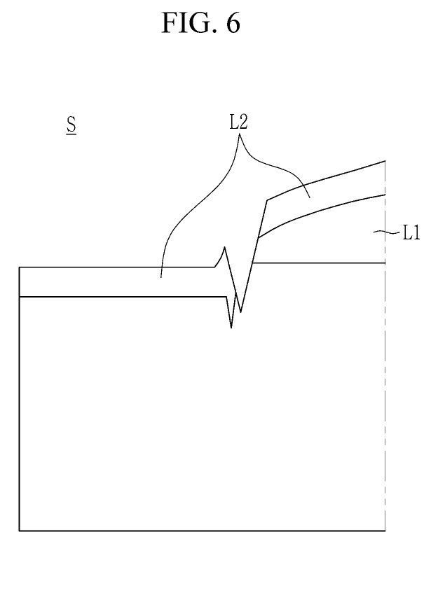

FIG. 6 is a view showing a bevel edge of the substrate S before the process is performed on the substrate; and FIG. 7 is a view showing the bevel edge of the substrate after the process is performed on the substrate.

Referring to FIGS. 6 and 7, a valley may be formed/disposed in an upper portion of the substrate S on which a first layer L1 and a second layer L2 such that the second layer L2 has a disconnected region before the processing on the substrate is performed. For example, a groove/valley/trench may be formed on an edge portion of the upper surface of the substrate S (e.g., on which other layers (L1/L2) may be formed) before the processing of the substrate S is performed. As an example, a first layer L1, and a second layer L2 disposed on the first layer L1 may be disposed on the substrate S before the processing of the substrate is performed. As an example, the first layer L1 may be a mold layer, and the second layer L2 may be a mask layer. The first layer L1 may be convex upward and disposed in a region of the substrate S that is adjacent to its edge. Accordingly, the second layer L2 disposed on the first layer L1 may also be convex upward. For example, the second layer L2 may be conformally formed on the first layer L1. In a subsequent process of the substrate S, another layer disposed on the second layer L2 may be removed/patterned through a photoresist (PR) application process, a development process, and an etching process. The first layer L1 and the second layer L2 are convex upward, thus causing a PR flow during the PR application process. Because of the flow of the PR, the PR may not have a uniform thickness, and may have a thin thickness in an inclined portion of the convex surface. Accordingly, a mask which does not have a sufficient thickness may be formed on the second layer L2 by the PR application process and the development process. When the etching process is performed in this state, an etched region may occur in the second layer L2 because the thin mask layer may expose the second layer L2 during the etching process, and a region of the second layer L2 may be disconnected, as shown in FIG. 6. When a subsequent process is performed while the region of the second layer L2 is disconnected in this way, an arc may occur in this disconnected region of the second layer L2.

The deposition layer DL may be formed in the bevel edge region of the substrate S when the deposition process is performed in the bevel edge region of the substrate S, as shown in FIG. 7. In addition, the deposition layer DL may fill the disconnected region of the second layer L2. In addition, if the deposition layer DL includes a carbon element, the second layer L2 may more effectively prevent the arc from occurring in the disconnected region of the second layer L2 during the subsequent process.

The carbon ion in the plasma state may be highly reactive with the substrate S. Accordingly, there is a risk that the deposition layer DL may be deposited in a region other than the bevel edge region of the substrate S. On the other hand, the substrate processing apparatus 1 according to an embodiment may supply the control gas in a form of the curtain between the process gas and the central region of the substrate S that is adjacent to the bevel edge region of the substrate S. Accordingly, the control gas may prevent the carbon ion from coming into contact with the substrate S, thereby preventing the deposition layer DL from being formed in a region other than the bevel edge region of the substrate S.

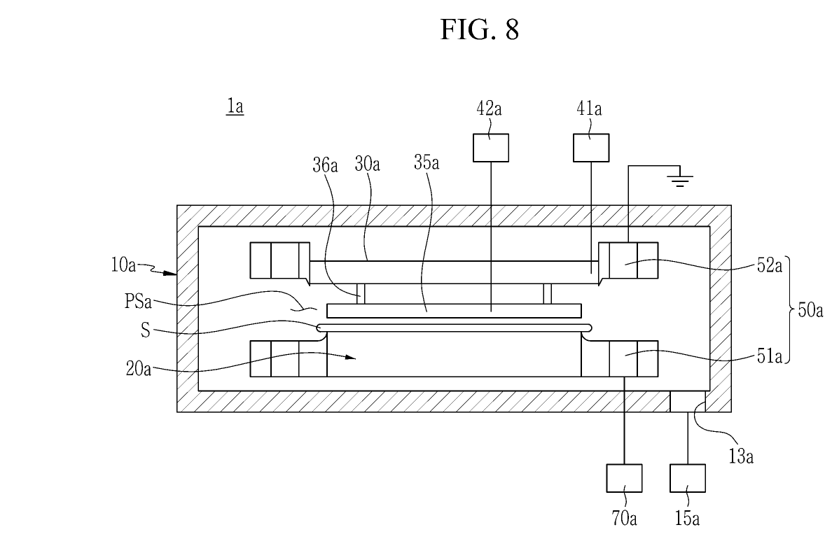

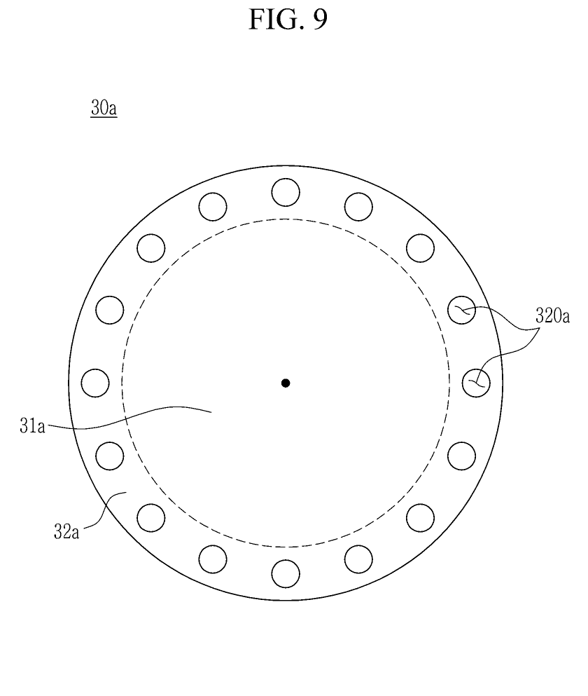

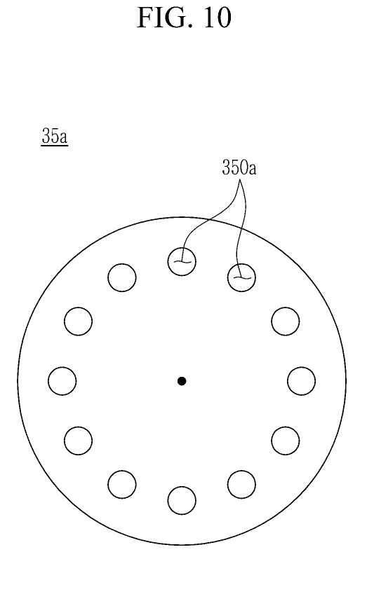

FIG. 8 is a view of a substrate processing apparatus 1a according to another embodiment; FIG. 9 is a bottom view of a shower head 30a shown in FIG. 8; and FIG. 10 is a bottom view of a plasma adjustment plate 35a shown in FIG. 8.

Referring to FIGS. 8 to 10, the substrate processing apparatus 1a according to another embodiment may include a chamber 10a, a support member 20a, the shower head 30a, the plasma adjustment plate 35a, an edge plasma excitation member 50a, and an excitation supply unit 70a.

The chamber 10a may provide therein a process space PSa used for performing the processing of the substrate S. An exhaust hole 13a may be disposed in one side of the chamber 10a. The exhaust hole 13a may be disposed in a lower region of the chamber 10a. As an example, the exhaust hole 13a may be disposed in a bottom wall or a bottom of the chamber 10a. An exhaust member 15a may be connected to the exhaust hole 13a. The exhaust member 15a may apply a negative pressure to the interior of the chamber 10a for the exhaust purpose. For example, the exhaust member 15a may apply the negative pressure to the interior of the chamber 10a by exhausting gas from the process space PSa.

Through the shower head 30a, the gas used for processing the substrate S may be sprayed into the process space PSa.

A lower surface of the shower head 30a may face the interior/center of the chamber 10a. The shower head 30a may be disposed in the chamber 10a. As an example, the shower head 30a may be manufactured separately from the chamber 10a and connected to (e.g., installed in) the chamber 10a.

The shower head 30a may be disposed in an upper portion of the process space PSa. The shower head 30a may have at least a partial region facing/overlapping the support member 20a in the vertical direction. The lower surface of the shower head 30a may have at least a partial region facing/overlapping an upper surface of the support member 20a in the vertical direction. A lower portion of the shower head 30a may be made of an insulating material. As an example, a region of the shower head 30a that faces/overlaps the upper surface of the support member 20a in the vertical direction may be made of the insulating material. In certain embodiments, an entire region of the lower surface of the shower head 30a may be made of the insulating material. An area of the lower surface of the shower head 30a may correspond to or the same as the area of the substrate S disposed on the support member 20a. The area of the lower surface of the shower head 30a may be greater than an area of the upper surface of the support member 20a.

A process gas supply member 41a may be connected to the shower head 30a. The process gas supply member 41a may supply the process gas to the shower head 30a. After the process gas is excited to the plasma state, at least some elements included in the process gas may be deposited on the substrate S to thus form a deposition layer. At least some elements included in the process gas may be deposited in the bevel edge region of the substrate S to thus form the deposition layer in the bevel edge region of the substrate S. The process gas may be a compound including a carbon atom. Accordingly, the process gas may supply the carbon ion when excited to the plasma state. As an example, the process gas may be acetylene (C₂H₂).

The plasma adjustment plate 35a may be disposed between the shower head 30a and the support member 20a. An upper surface of the plasma adjustment plate 35a may be spaced apart from the lower surface of the shower head 30a in the up-and-down direction. The plasma adjustment plate 35a may be connected to the shower head 30a. As an example, the plasma adjustment plate 35a may be connected to the shower head 30a by a connection rod 36a. The plasma adjustment plate 35a may be movable in the up-and-down direction. As an example, an upper portion of the connection rod 36a may be insertable into the shower head 30a. For example, a length of the connection rod 36a inserted into the shower head 30a may be changeable. As the length of the connection rod 36a inserted into the shower head 30a is changed, a separation distance between the plasma adjustment plate 35a and the shower head 30a may be adjusted, thus moving the plasma adjustment plate 35a in the up-and-down direction. The separation distance between a lower surface of the plasma adjustment plate 35a and the upper surface of the support member 20a in the up-and-down direction may be adjusted by the movement of the plasma adjustment plate 35a in the up-and-down direction.

A lower surface of the shower head 30a may include a central region 31a and an edge spray region 32a.

The central region 31a may have a predetermined area. The area of the central region 31a may be the same as or smaller than the area of the plasma adjustment plate 35a. The central region 31a may be disposed/positioned within the region of the shower head 30 that faces/overlaps the plasma adjustment plate 35a in the vertical direction.

The edge spray region 32a may be disposed/placed around an outer perimeter of the central region 31a. The edge spray region 32a may be formed in a ring shape. FIG. 9 shows a case where the central region 31a has a circular shape. However, the shape of the central region 31a is not limited to this shape, and may have a polygonal shape, another shape, or the like.

A process gas spray hole 320a may be disposed in the lower surface of the shower head 30a. A plurality of process gas spray holes 320a may be provided in the lower surface of the shower head 30a. The process gas spray hole 320a may be disposed in the edge spray region 32a of the shower head 30a. The process gas spray hole 320a may be connected to the process gas supply member 41a. Accordingly, the process gas supplied by the process gas supply member 41a may be sprayed into a space below the shower head 30a through the process gas spray hole 320a.

The lower surface of the plasma adjustment plate 35a may be made of an insulating material, e.g., the same insulating material as the lower portion of the shower head 30a. In certain embodiments, an entire outer surface of the plasma adjustment plate 35a may be made of the insulating material. The lower surface of the plasma adjustment plate 35a may face/overlap the upper surface of the support member 20a in the vertical direction. An area of the plasma adjustment plate 35a, e.g., in a plan view, may be smaller than the area of the lower surface of the shower head 30a. The area of the plasma adjustment plate 35a may be smaller than the area of the substrate S, e.g., in the plan view. The area of the plasma adjustment plate 35a, e.g., in the plan view, may correspond to the area of the upper surface of the support member 20a.

A control gas supply member 42a may be connected to the plasma adjustment plate 35a. The control gas supply member 42a may supply the deposition control gas to the plasma adjustment plate 35a. The deposition control gas may adjust/control the degree to which the deposition layer is deposited on the substrate S. For example, the deposition control gas may adjust positions of the process gas and/or dilute portions of the process gas, e.g., by mixing with the process gas and/or by controlling amount/pressure of the deposition control gas such that positions/thicknesses of the deposition layer DL is controlled by the deposition control gas. The deposition control gas may prevent the deposition layer from being formed in the region other than the bevel edge region of the substrate S. The deposition control gas may be an inert gas. For example, the deposition control gas may be a gas selected from the group consisting of nitrogen, argon, neon, helium, and the combination thereof.

A control gas spray hole 350a may be disposed in the lower surface of the plasma adjustment plate 35a. A plurality of control gas spray holes 350a may be provided in the lower surface of the plasma adjustment plate 35a. The control gas spray hole 350a may be connected to the control gas supply member 42a. Accordingly, the control gas supplied by the control gas supply member 42a may be sprayed into a space below the plasma adjustment plate 35a through the control gas spray hole 350a. The control gas spray hole 350a may be inclined in the same or similar manner as described above with reference to FIG. 3.

The control gas sprayed from the control gas spray hole 350a may flow through a space between the substrate S and the plasma adjustment plate 35a toward the edge region of the substrate S. Accordingly, it is possible to prevent the deposition layer from being formed in the region other than the bevel edge region of the substrate S.

The edge plasma excitation member 50a may include a lower edge electrode 51a and an upper edge electrode 52a. The excitation supply unit 70a may be electrically connected to the edge plasma excitation member 50a.

The remaining configurations and functions of the substrate processing apparatus 1a may be identical or similar to those of the substrate processing apparatus 1 described above with reference to FIGS. 1 to 7, and their repeated descriptions are thus omitted.

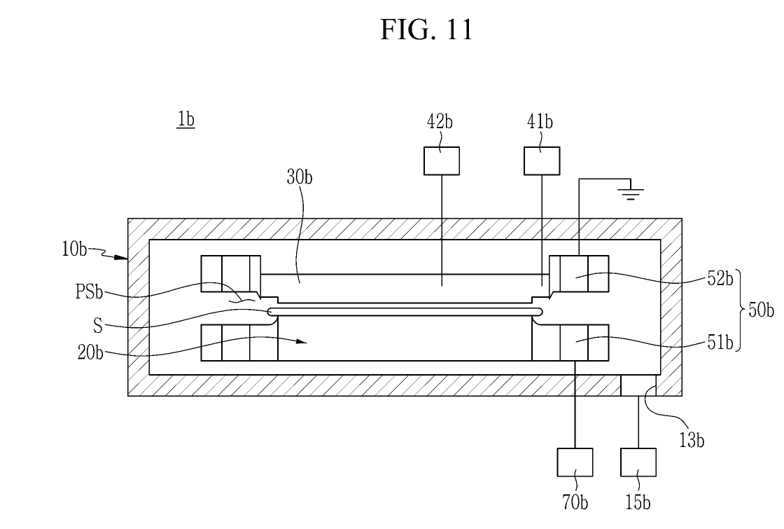

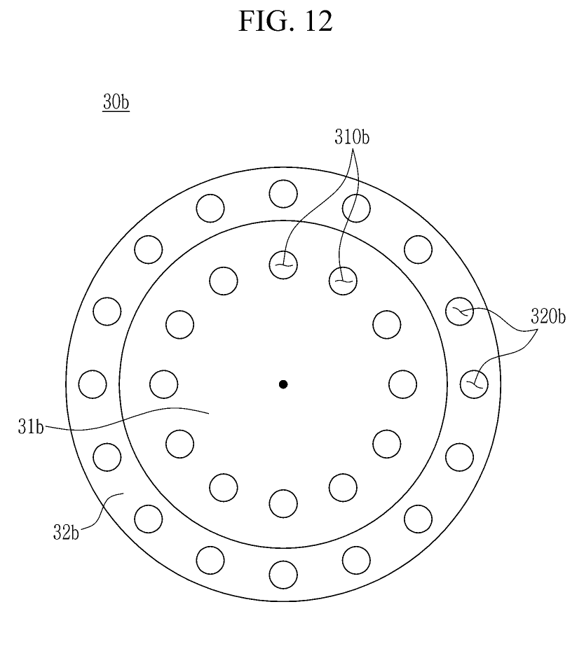

FIG. 11 is a cross-sectional view of a substrate processing apparatus 1b according to still another embodiment; and FIG. 12 is a bottom view of a shower head 30b shown in FIG. 11.

Referring to FIGS. 11 and 12, the substrate processing apparatus 1b according to the present embodiment may include a chamber 10b, a support member 20b, the shower head 30b, an edge plasma excitation member 50b, and an excitation supply unit 70b.

The chamber 10b may provide therein a process space PSb used for performing the processing of the substrate. An exhaust hole 13b may be disposed in one side of the chamber 10b. The exhaust hole 13b may be disposed in a lower region of the chamber 10b. As an example, the exhaust hole 13b may be disposed in a bottom wall or bottom surface of the chamber 10b. An exhaust member 15b may be connected to the exhaust hole 13b. The exhaust member 15b may apply a negative pressure to the interior of the chamber 10b for the exhaust purpose. For example, the exhaust member 15b may apply the negative pressure to the interior of the chamber 10b by exhausting gas from the process space PSb.

Through the shower head 30b, the gas used for processing the substrate S may be sprayed into the process space PSb.

A lower surface of the shower head 30b may face the interior/center of the chamber 10b. The shower head 30b may be disposed in the chamber 10b. As an example, the shower head 30b may be manufactured separately from the chamber 10b and connected to or installed in the chamber 10b. The shower head 30b may be movable in the up-and-down direction. Accordingly, a separation distance between the lower surface of the shower head 30b and an upper surface of the support member 20b may be adjusted. The separation distance between the shower head 30b and the substrate S may be adjusted in the processing of the substrate S.

The shower head 30b may be disposed in an upper portion of the process space PSb. The shower head 30b may have at least a partial region facing/overlapping the support member 20b in the vertical direction. The lower surface of the shower head 30b may have at least a partial region facing/overlapping the upper surface of the support member 20b in the vertical direction. A lower portion of the shower head 30b may be made of an insulating material. As an example, a region of the shower head 30b that faces/overlaps the upper surface of the support member 20b in the vertical direction may be made of the insulating material. In certain embodiments, an entire region of the lower surface of the shower head 30b may be made of the insulating material. An area of the lower surface of the shower head 30b may correspond to or the same as the area of the substrate S disposed on the support member 20b, e.g., in a plan view. The area of the lower surface of the shower head 30b, e.g., in a plan view, may be greater than an area of the upper surface of the support member 20b.

A process gas supply member 41b and a control gas supply member 42b may be connected to the shower head 30b. The process gas supply member 41b may supply the process gas to the shower head 30b. After the process gas is excited to the plasma state, at least some elements included in the process gas may be deposited on the substrate S to thus form a deposition layer. At least some elements included in the process gas may be deposited in the bevel edge region of the substrate S to thus form the deposition layer in the bevel edge region of the substrate S. The process gas may be a compound including a carbon atom. Accordingly, the process gas may supply the carbon ion when excited to the plasma state. As an example, the process gas may be acetylene (C₂H₂). The control gas supply member 42b may supply the deposition control gas to the shower head 30b. The deposition control gas may adjust the degree to which the deposition layer is deposited on the substrate S. For example, the deposition control gas may adjust positions of the process gas and/or dilute portions of the process gas, e.g., by mixing with the process gas and/or by controlling amount/pressure of the deposition control gas such that positions/thicknesses of the deposition layer DL is controlled by the deposition control gas. The deposition control gas may prevent the deposition layer from being formed in the region other than the bevel edge region of the substrate S. The deposition control gas may be an inert gas. For example, the deposition control gas may be a gas selected from the group consisting of nitrogen, argon, neon, helium, and the combination thereof.

A lower surface of the shower head 30b may include a central region 31b and an edge spray region 32b.

The central region 31b may have a predetermined area. An area of the central region 31b may be smaller than the area of the substrate S, e.g., in a plan view. The area of the central region 31b may correspond to or the same as an area of the upper surface of the support member 20b. When the substrate S is disposed on the support member 20b, the bevel edge region of the substrate S may face/overlap the edge spray region 32b in the vertical direction.

The edge spray region 32b may be disposed around an outer perimeter of the central region 31b. The edge spray region 32b may be formed in a ring shape. FIG. 12 shows a case where the central region 31b has a circular shape. However, the shape of the central region 31b is not limited to this shape, and may have a polygonal shape, another shape, or the like.

The central region 31b may protrude downward toward the support member 20b and the substrate S disposed on the support member 20b more than the edge spray region 32b. For example, the central region 31b may protrude downward the edge spray region 32b. A lower surface of the central region 31b may be made of an insulating material.

Gas spray holes 310b and 320b may be disposed in the lower surface of the shower head 30b. Through the gas spray holes 310b and 320b, the gas may be sprayed into a space below the shower head 30b. The gas spray holes 310b and 320b may include a control gas spray hole 310b and a process gas spray hole 320b.

The process gas spray hole 320b may be disposed in the edge spray region 32b of the shower head 30b. A plurality of process gas spray holes 320b may be provided in the edge spray region 32b of the shower head 30b. The process gas spray hole 320b may be connected to the process gas supply member 41b. Accordingly, the process gas supplied by the process gas supply member 41b may be sprayed into the space below the shower head 30b through the process gas spray hole 320b.

The control gas spray hole 310b may be disposed in the central region 31b of the shower head 30b. A plurality of control gas spray holes 310b may be provided in the central region 31b of the shower head 30b. The control gas spray hole 310b may be connected to the control gas supply member 42b. Accordingly, the control gas supplied by the control gas supply member 42b may be sprayed into the space below the shower head 30b through the control gas spray hole 310b. The control gas spray hole 310b may be inclined in the same or similar manner as described above with reference to FIG. 3.

The control gas sprayed from the control gas spray hole 310a may flow through a space between the substrate S and the central region 31b of the shower head 30b toward the edge region of the substrate S. Accordingly, it is possible to prevent the deposition layer from being formed in the region other than the bevel edge region of the substrate S.

In addition, the process gas spray hole 320b may face the bevel edge region of the substrate S, thus allowing the process gas for forming the deposition layer to be effectively supplied to the bevel edge region of the substrate S.

The edge plasma excitation member 50b may include a lower edge electrode 51b and an upper edge electrode 52b. The excitation supply unit 70b may be electrically connected to the edge plasma excitation member 50b.

The remaining configurations and functions of the substrate processing apparatus 1b may be identical or similar to those of the substrate processing apparatus 1 described above with reference to FIGS. 1 to 7, and their repeated descriptions are thus omitted.

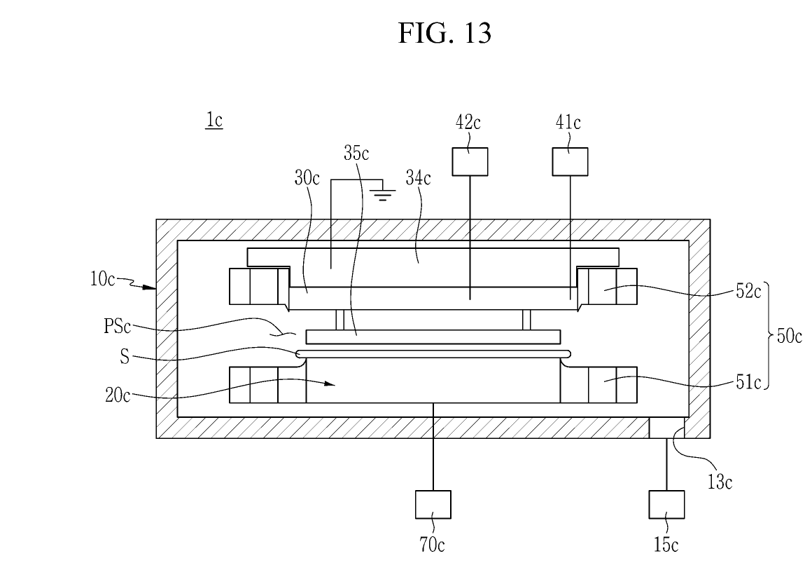

FIG. 13 is a cross-sectional view of a substrate processing apparatus 1c according to yet another embodiment.

Referring to FIG. 13, the substrate processing apparatus 1c according to the present embodiment may include a chamber 10c, a support member 20c, a shower head 30c, a plasma adjustment plate 35c, an edge plasma excitation member 50c, and an excitation supply unit 70c.

The chamber 10c may provide therein a process space PSc used for performing the processing of the substrate. An exhaust hole 13c may be disposed in one side of the chamber 10c. The exhaust hole 13c may be disposed in a lower region of the chamber 10c. As an example, the exhaust hole 13c may be disposed in a bottom wall/surface of the chamber 10c. An exhaust member 15c may be connected to the exhaust hole 13c. The exhaust member 15c may apply a negative pressure to the interior of the chamber 10c for the exhaust purpose. For example, the exhaust member 15c may apply the negative pressure to the interior of the chamber 10c by exhausting gas from the process space PSc.

The edge plasma excitation member 50c may include a lower edge electrode 51c and an upper edge electrode 52c. The excitation supply unit 70c may be electrically connected to the edge plasma excitation member 50c. As an example, the support member 20c may have at least a partial region made of a conductive material. As an example, the support member 20c may have at least a partial region made of a metal. Accordingly, the support member 20c may function as a lower electrode. A region of the support member 20c that is made of the conductive material may be disposed within an internal region of the support member 20c.

In addition, an upper electrode 34c may be disposed above the support member 20c. The upper electrode 34c may be disposed on an upper side of or above the shower head 30c. In certain embodiments, the shower head 30c may have at least a partial region made of a conductive material, e.g., the same conductive material as in the support member 20c and/or in the upper electrode 34c. Accordingly, the shower head 30c may function as an upper electrode.

In addition, the excitation supply unit 70c may be electrically connected to at least one of the support member 20c and the upper electrode 34c. For example, the excitation supply unit 70c may be electrically connected to the support member 20c, and the upper electrode 34c may be grounded. In some embodiments, the excitation supply unit 70c may be electrically connected to the upper electrode 34c, and the support member 20c may be grounded. In certain embodiments, the excitation supply unit 70c may be electrically connected to the support member 20c and the upper electrode 34c. FIG. 13 shows a case where the excitation supply unit 70c is electrically connected to the support member 20c and the upper electrode 34c is grounded.

The lower edge electrode 51c may be electrically coupled to the support member 20c. The upper edge electrode 52c may be electrically coupled to the upper electrode 34c. Accordingly, the edge plasma excitation member 50c may be electrically connected to the excitation supply unit 70c.

The remaining configurations and functions of the substrate processing apparatus 1c may be identical or similar to those of the substrate processing apparatus 1 described above with reference to FIGS. 1 to 7. For example, a process gas supply member 41c and a control gas supply member 42c may be connected to the shower head 30c. In some embodiments, the remaining configurations and functions of the substrate processing apparatus 1c may be identical or similar to those of the substrate processing apparatus 1a described above with reference to FIGS. 8 to 10. For example, the process gas supply member 41c may be connected to the shower head 30c, and the control gas supply member 42c may be connected to the plasma adjustment plate 35c. In certain embodiments, the remaining configurations and functions of the substrate processing apparatus 1c may be identical or similar to those of the substrate processing apparatus 1b described above with reference to FIGS. 11 and 12. For example, the plasma adjustment plate 35c may be omitted. FIG. 13 shows a case where the remaining configurations of the substrate processing apparatus 1c are identical or similar to those described with reference to FIGS. 1 to 7. Repeated descriptions of the identical or similar configurations and their functions are omitted.

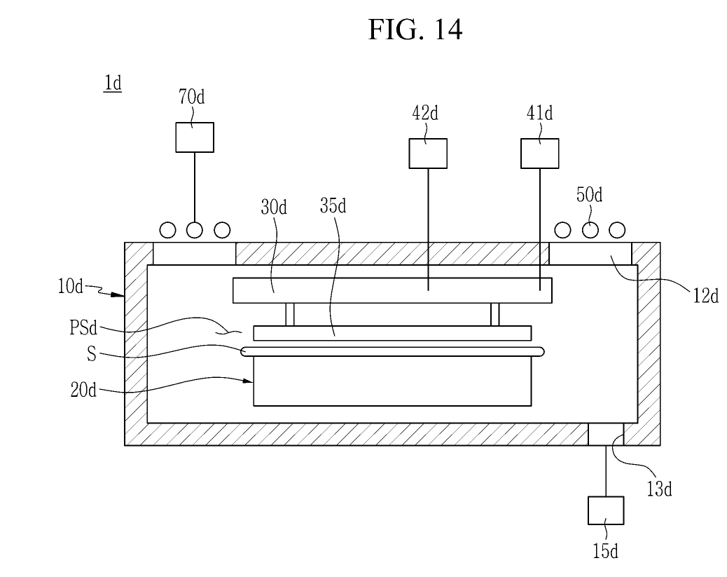

FIG. 14 is a cross-sectional view of a substrate processing apparatus 1d according to a further embodiment.

Referring to FIG. 14, the substrate processing apparatus 1d according to the present embodiment may include a chamber 10d, a support member 20d, a shower head 30d, a plasma adjustment plate 35d, an edge plasma excitation member 50d, and an excitation supply unit 70d.

The chamber 10d may provide therein a process space PSd used for performing the processing of the substrate. An exhaust hole 13d may be disposed in one side of the chamber 10d. The exhaust hole 13d may be disposed in a lower region of the chamber 10d. As an example, the exhaust hole 13d may be disposed in a bottom wall/surface of the chamber 10d. An exhaust member 15d may be connected to the exhaust hole 13d. The exhaust member 15d may apply a negative pressure to the interior of the chamber 10d for the exhaust purpose. For example, the exhaust member 15d may apply the negative pressure to the interior of the chamber 10d by exhausting gas from the process space PSd.

The edge plasma excitation member 50d may apply the energy for exciting plasma to the interior of the chamber 10d. The edge plasma excitation member 50d may have an antenna structure. The edge plasma excitation member 50d may be disposed outside the chamber 10d. The edge plasma excitation member 50d may be disposed to be adjacent to or on an upper surface of a top wall or cover of the chamber 10d. The edge plasma excitation member 50d may face an internal space of the chamber 10d while having the top wall or an upper housing of the chamber 10d therebetween. At least a portion of the edge plasma excitation member 50d may be disposed outside the space where the edge plasma excitation member 50d faces the support member 20d in the vertical direction. For example, at least a portion of the edge plasma excitation member 50d may not vertically overlap the support member 20d. Accordingly, the edge plasma excitation member 50d may effectively apply an energy for exciting plasma to a bevel edge region of the substrate S disposed on the support member 20d.

A region of the top wall or upper housing of the chamber 10d that faces/overlaps the edge plasma excitation member 50d in the up-and-down direction may include a transmission window 12d. The transmission window 12d may be made of a material that is transparent to electromagnetic waves, such as quartz.

The remaining configurations and functions of the substrate processing apparatus 1d may be identical or similar to those of the substrate processing apparatus 1 described above with reference to FIGS. 1 to 7. For example, a process gas supply member 41d and a control gas supply member 42d may be connected to the shower head 30d. In some embodiments, the remaining configurations and functions of the substrate processing apparatus 1d may be identical or similar to those of the substrate processing apparatus 1a described above with reference to FIGS. 8 to 10. For example, the process gas supply member 41d may be connected to the shower head 30d, and the control gas supply member 42d may be connected to the plasma adjustment plate 35d. In certain embodiments, the remaining configurations and functions of the substrate processing apparatus 1d may be identical or similar to those of the substrate processing apparatus 1b described above with reference to FIGS. 11 and 12. For example, the plasma adjustment plate 35d may be omitted. FIG. 13 shows a case where the remaining configurations of the substrate processing apparatus 1d are identical or similar to those described with reference to FIGS. 1 to 7. Repeated descriptions of the identical or similar configurations and their functions are omitted.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

Although the embodiments of the present disclosure have been described in detail hereinabove, the scope of the present inventive concept is not limited thereto. That is, various modifications and alterations made by those skilled in the art that use a basic concept of the present disclosure as defined in the following claims also fall within the scope of the present inventive concept.

### Description of the symbols

10: chamber

20: support member

30: shower head

31: central region

32: edge spray region

35: plasma adjustment plate

41: process gas supply member

42: control gas supply member

50: edge plasma excitation member

51: lower edge electrode

52: upper edge electrode

61: lower dielectric ring

62: lower outer dielectric ring

63: upper dielectric ring

64: upper outer dielectric ring

70: excitation supply unit

310: control gas spray hole

320: process gas spray hole

What is claimed is:

1. A substrate processing apparatus comprising:
a chamber providing a process space;
a support member disposed in the chamber and configured to support a substrate; and
a shower head disposed in the chamber and configured to spray a gas,
wherein the shower head includes a central region and an edge spray region disposed around an outer perimeter of the central region,
a control gas spray hole is disposed in the central region, and a process gas spray hole is disposed in the edge spray region.

2. The apparatus of claim 1, further comprising
an edge plasma excitation member configured to apply energy for exciting plasma to the process space.

3. The apparatus of claim 2, wherein
the edge plasma excitation member includes
a lower edge electrode disposed around an outer perimeter of the support member, and
an upper edge electrode disposed around an outer perimeter of the shower head.

4. The apparatus of claim 2, wherein
the edge plasma excitation member has an antenna structure and is disposed outside the chamber.

5. The apparatus of claim 1, further comprising
a process gas supply member connected to the process gas spray hole and configured to supply a process gas, which is a compound including a carbon atom.

6. The apparatus of claim 1, further comprising
a process gas supply member connected to the process gas spray hole and configured to supply a process gas, which is acetylene (C₂H₂).

7. The apparatus of claim 1, further comprising
a control gas supply member connected to the control gas spray hole and configured to supply a control gas, which is an inert gas.

8. The apparatus of claim 1, wherein
an area of a lower surface of the shower head is greater than an area of an upper surface of the support member.

9. The apparatus of claim 1, further comprising
a plasma adjustment plate disposed between the shower head and the support member.

10. The apparatus of claim 9, wherein
the plasma adjustment plate is movable in an up-and-down direction.

11. The apparatus of claim 9, wherein
an area of the plasma adjustment plate is the same as the area of an upper surface of the support member.

12. The apparatus of claim 9, wherein
the central region is disposed within a region of the shower head that overlaps the plasma adjustment plate in a vertical direction.

13. The apparatus of claim 9, wherein
a lower surface of the plasma adjustment plate is made of an insulating material.

14. The apparatus of claim 1, wherein
the central region protrudes downward form the edge spray region.

15. A substrate processing apparatus comprising:
a chamber providing a process space;
a support member disposed in the chamber and configured to support a substrate;
a shower head disposed in the chamber and configured to spray a gas;
a process gas supply member connected to the shower head and configured to supply a process gas;
a control gas supply member connected to the shower head and configured to supply a control gas; and
an edge plasma excitation member configured to apply energy for exciting plasma to the process space,
wherein the shower head includes a central region and an edge spray region disposed around an outer perimeter of the central region,
a control gas spray hole configured to spray the control gas is disposed in the central region, and a process gas spray hole configured to spray the process gas is disposed in the edge spray region.

16. The apparatus of claim 15, wherein
the control gas is an inert gas, and the process gas is a compound including a carbon atom.

17. The apparatus of claim 15, wherein
an area of a lower surface of the shower head is greater than an area of an upper surface of the support member, and the central region protrudes downward from the edge spray region.

18. A substrate processing apparatus comprising:
a chamber providing a process space;
a support member disposed in the chamber and configured to support a substrate;
a shower head disposed in the chamber and configured to spray a gas;
a process gas supply member connected to the shower head and configured to supply a process gas;
a control gas supply member connected to the shower head and configured to supply a control gas;
a plasma adjustment plate disposed between the shower head and the support member; and
an edge plasma excitation member configured to apply energy for exciting plasma to the process space,
wherein the shower head includes a central region and an edge spray region disposed around an outer perimeter of the central region,
a control gas spray hole configured to spray the control gas is disposed in the central region, and a process gas spray hole configured to spray the process gas is disposed in the edge spray region.

19. The apparatus of claim 18, wherein
an area of the plasma adjustment plate is the same as an area of an upper surface of the support member, and the plasma adjustment plate is movable in an up-and-down direction.

20. The apparatus of claim 18, wherein
an area of a lower surface of the shower head is greater than an area of an upper surface of the support member, and the central region is disposed within a region of the shower head that overlaps the plasma adjustment plate in a vertical direction.
